(19) United States
(12) Patent Application Publication
(10) Pub. No.: US 2018/0122922 A1
(43) Pub. Date: May 3, 2018

(54) SEMICONDUCTOR DEVICES

(71) Applicant: Samsung Electronics Co., Ltd., Suwon-si (KR)

(72) Inventors: SEOKHOON KIM, Suwon-si (KR); WOO BIN SONG, Hwaseong-si (KR); SUNJUNG KIM, Suwon-si (KR); JinBum KIM, Seoul (KR); SANGMOON LEE, Suwon-si (KR); SEUNG HUN LEE, Hwaseong-si (KR); DONGSUK SHIN, Yongin-si (KR)

(21) Appl. No.: 15/800,242

(22) Filed: Nov. 1, 2017

(30) Foreign Application Priority Data
Nov. 3, 2016 (KR) 10-2016-0145955

(51) Int. Cl. H01L 29/66; H01L 29/423; H01L 29/78; H01L 21/762; H01L 23/31

(52) U.S. Cl. CPC H01L 29/66795; H01L 29/42364; H01L 29/20; H01L 21/76224; H01L 23/3171; H01L 29/785

(57) ABSTRACT

Disclosed is a semiconductor device. The semiconductor device comprises a fin structure on a substrate, device isolation patterns provided on the substrate and disposed on opposite sides of the fin structure, a gate electrode running across the fin structure and the device isolation patterns, a gate dielectric pattern between the gate electrode and the fin structure and between the gate electrode and the device isolation patterns, and a capping layer between the substrate and the device isolation patterns and between the fin structure and the device isolation patterns. The capping layer has a thickness greater than a thickness of the gate dielectric pattern.

### CROSS-REFERENCE TO RELATED APPLICATIONS

This U.S. nonprovisional patent application claims priority under 35 U.S.C § 119 to Korean Patent Application No. 10-2016-0145955 filed on Nov. 3, 2016 entire contents of which are hereby incorporated by reference.

### BACKGROUND

The present disclosure relates to a semiconductor device, and more particularly, to a semiconductor device including a fin field effect transistor.

Semiconductor devices include integrated circuits consisting of metal oxide semiconductor field effect transistors (MOSFETs). As sizes and design rules of the semiconductor devices are gradually decreased, sizes of the MOSFETs are also increasingly scaled down. The scale down of MOSFETs may ameliorate operating characteristics of the semiconductor devices. Accordingly, various researches have been developed to form semiconductor devices having superior performances while overcoming limitations due to integration of the semiconductor devices.

### SUMMARY

Embodiments of the present disclosure provide a semiconductor device and a method of fabricating a semiconductor device having enhanced electrical characteristics.

According to exemplary embodiments of the present disclosure, a semiconductor device may comprise: a fin structure on a substrate; device isolation patterns provided on the substrate and disposed on opposite sides of the fin structure; a gate electrode crossing the fin structure and the device isolation patterns; a gate dielectric pattern between the gate electrode and the fin structure and between the gate electrode and the device isolation patterns; and a capping layer between the substrate and the device isolation patterns and between the fin structure and the device isolation patterns. The capping layer may have a thickness greater than a thickness of the gate dielectric pattern.

According to exemplary embodiments of the present disclosure, a semiconductor device may comprise: a buffer layer on a substrate; a fin structure protruding from the buffer layer; and a gate electrode crossing the fin structure. The fin structure may comprise: a buffer pattern on the buffer layer; a channel pattern on the buffer pattern; and a capping pattern on the channel pattern. The capping pattern may have a thickness less than a thickness of the channel pattern.

According to exemplary embodiments of the present disclosure, a semiconductor device may comprise: a fin structure on a substrate; a buffer layer between the substrate and the fin structure; device isolation patterns provided on the substrate and disposed on opposite sides of the fin structure, the device isolation patterns being spaced apart from each other along the first direction across the fin structure and extending along a second direction on the substrate; a gate structure crossing the fin structure and the device isolation patterns in the first direction; and a capping layer between the substrate and the devices isolation patterns and between the fin structure and the device isolation patterns, the capping layer having a top surface at a same level as a top surface of the device isolation patterns and at a lower level from the substrate than a top surface of the fin structure.

Details of other exemplary embodiments are included in the description and drawings.

### BRIEF DESCRIPTION OF THE DRAWINGS

FIG. 1 is a flow chart illustrating a method of fabricating a semiconductor device according to exemplary embodiments of the present disclosure.

FIGS. 2A to 2I are perspective views illustrating a method of fabricating a semiconductor device according to FIG. 1.

FIG. 3 is a cross-sectional view taken along lines A-A′ and B-B′ of FIG. 2I, illustrating a semiconductor device according to exemplary embodiments of the present disclosure.

FIG. 4 is a flow chart illustrating a method of fabricating a semiconductor device according to exemplary embodiments of the present disclosure.

FIGS. 5A to 5H are perspective views illustrating a method of fabricating a semiconductor device in accordance with FIG. 4.

FIG. 6 is a cross-sectional view taken along lines C-C′ and D-D′ of FIG. 5G, illustrating a semiconductor device according to exemplary embodiments of the present disclosure.

FIG. 7 is a perspective view illustrating a semiconductor device according to exemplary embodiments of the present disclosure.

FIG. 8 is a cross-sectional view taken along lines E-E′ and F-F′ of FIG. 7.

FIG. 9 is a perspective view illustrating a semiconductor device according to exemplary embodiments of the present disclosure.

FIG. 10 is a cross-sectional view taken along lines G-G′ and H-H′ of FIG. 9.

### DETAILED DESCRIPTION OF EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, like numbers refer to like elements throughout. Though the different figures show various features of exemplary embodiments, these figures and their features are not necessarily intended to be mutually exclusive from each other. Rather, certain features depicted and described in a particular figure may also be implemented with embodiment(s) depicted in different figure(s), even if such a combination is not separately illustrated. Referencing such features/figures with different embodiment labels (e.g. “first embodiment”) should not be interpreted as indicating certain features of one embodiment are mutually exclusive of and are not intended to be used with another embodiment.

Unless the context indicates otherwise, the terms first, second, third, etc., are used as labels to distinguish one element, component, region, layer or section from another element, component, region, layer or section (that may or may not be similar). Thus, a first element, component, region, layer or section discussed below in one section of the specification (or claim) may be referred to as a second element, component, region, layer or section in another section of the specification (or another claim).

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

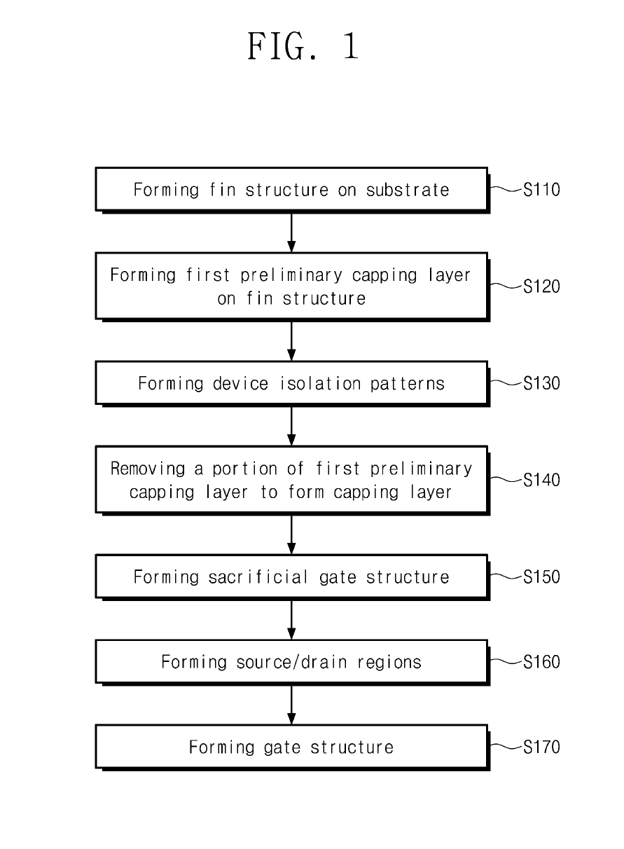

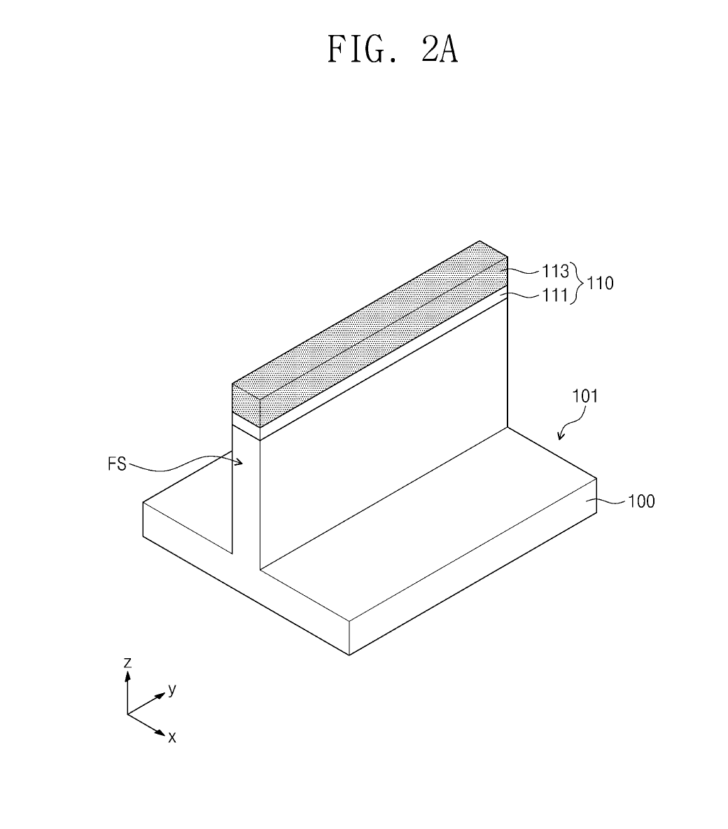

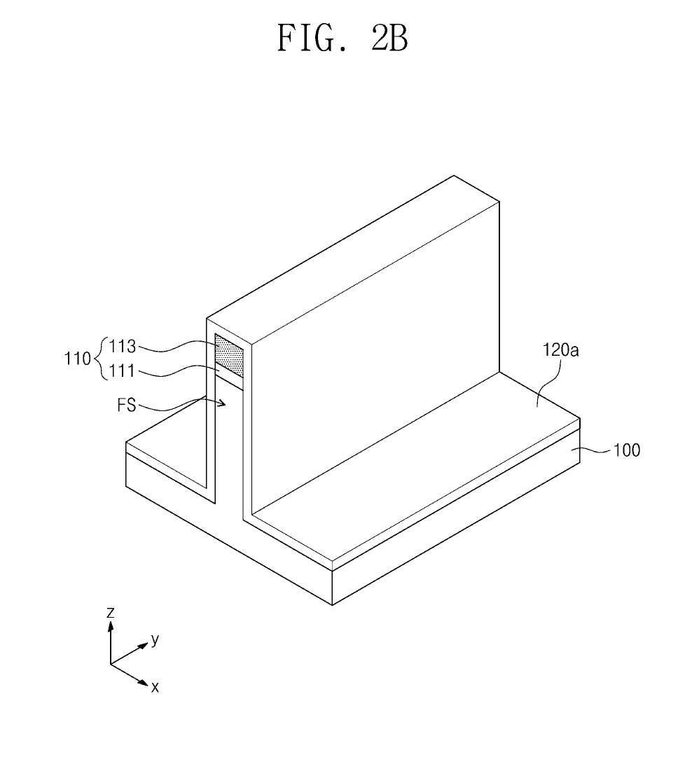

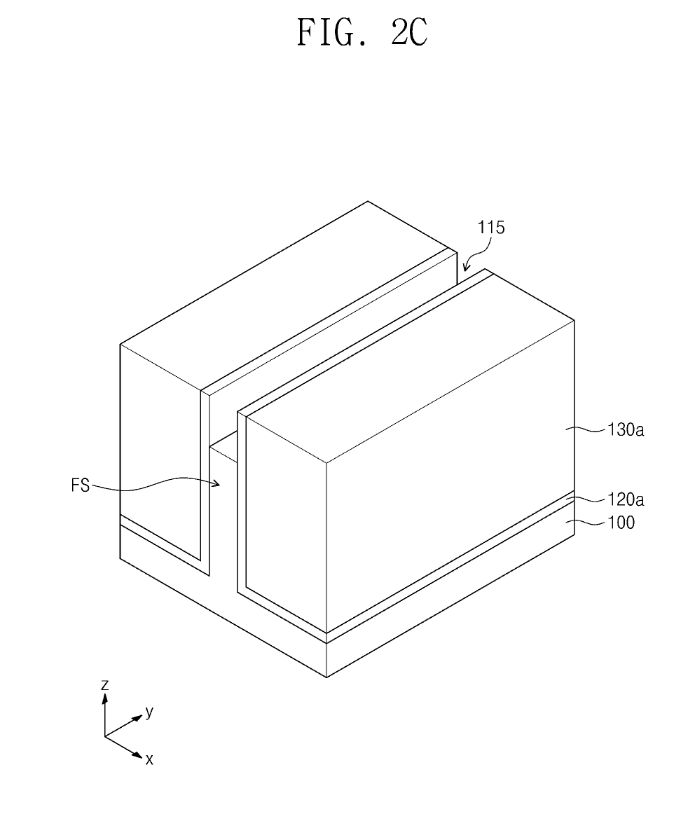

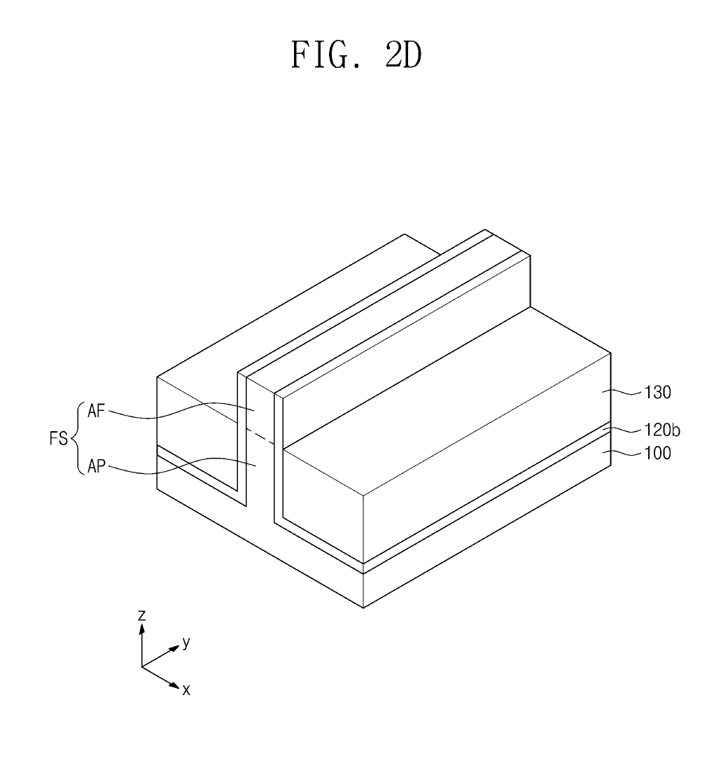

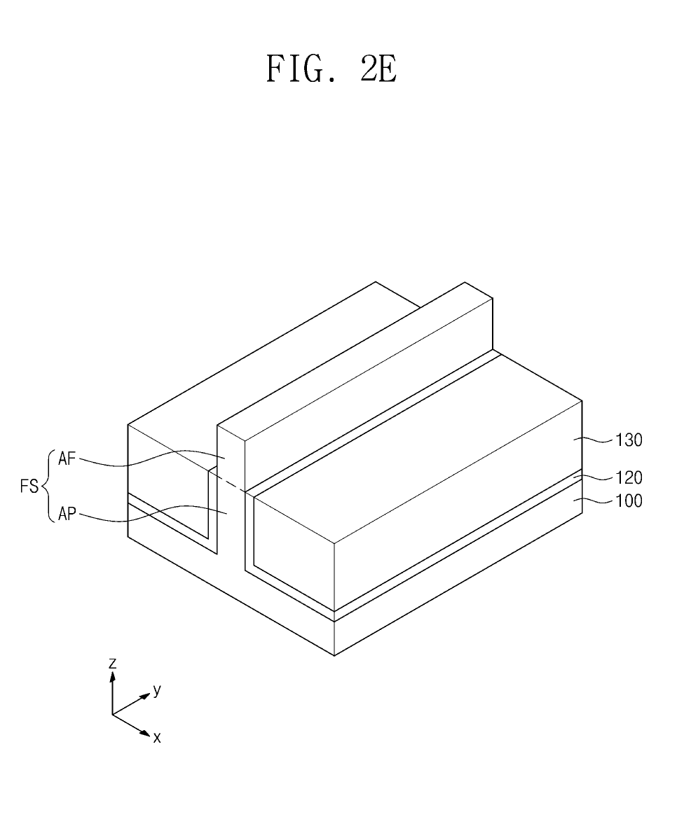

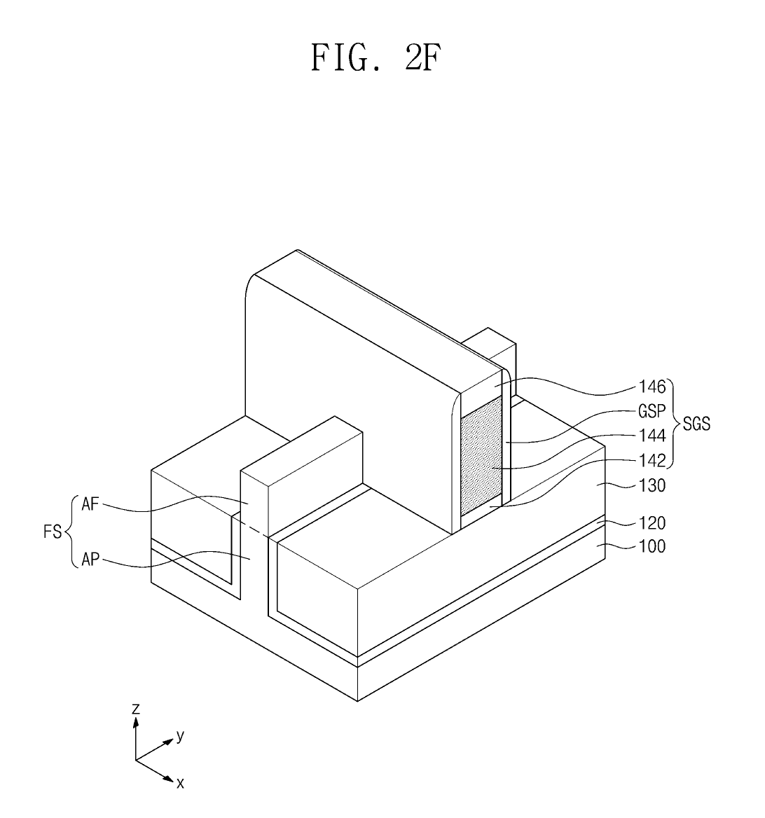

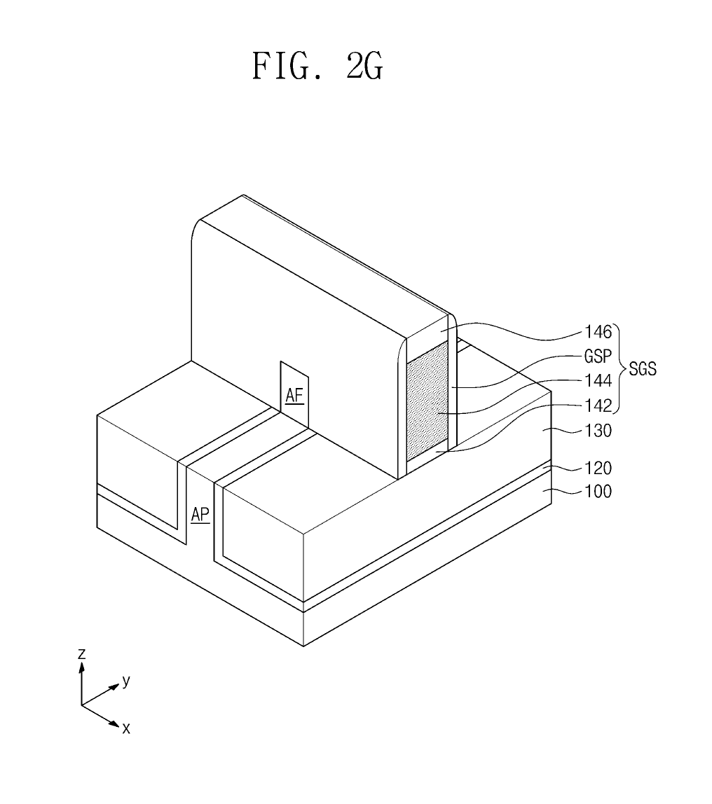

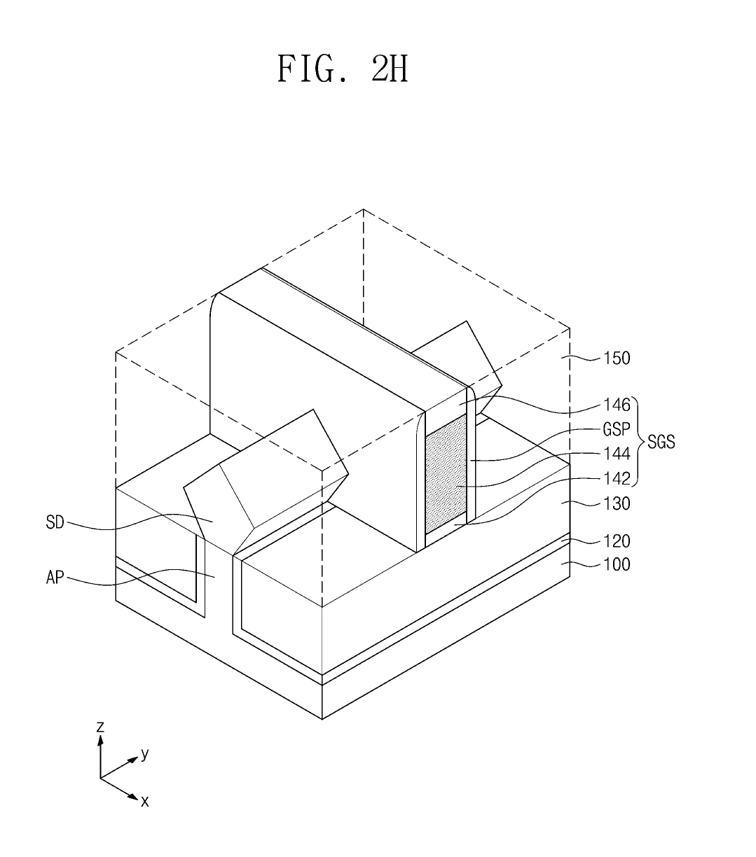

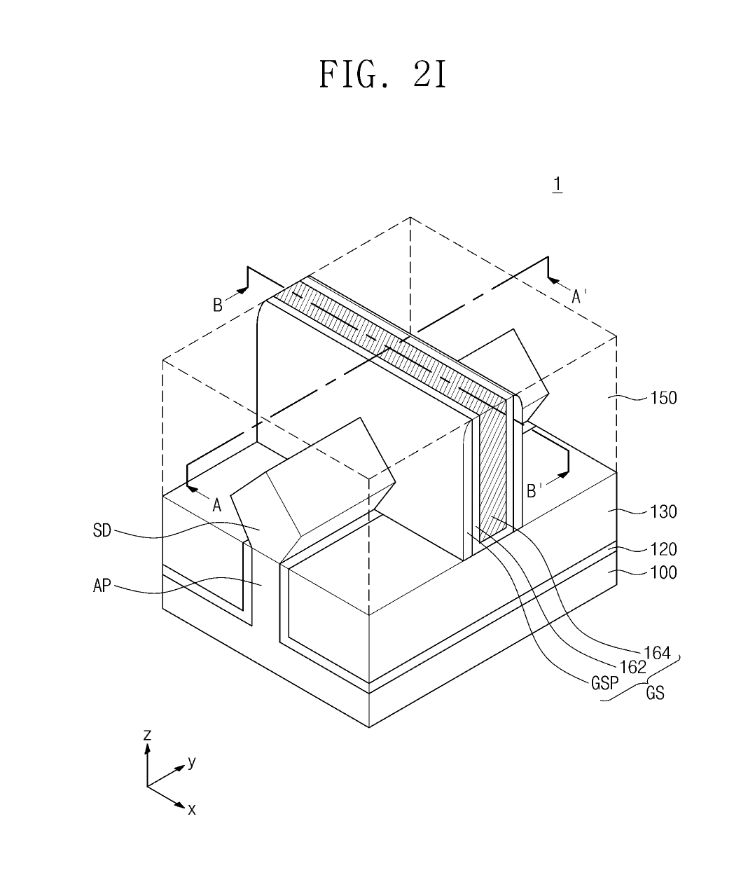

FIG. 1 is a flow chart illustrating a method of fabricating a semiconductor device according to exemplary embodiments of the present disclosure. FIGS. 2A to 2I are perspective views illustrating a method of fabricating a semiconductor device 1 in accordance with FIG. 1. It will be described a method of fabricating the semiconductor device 1 according to exemplary embodiments of the present disclosure with reference to FIGS. 1 to 2I.

As used herein, a semiconductor device 1 may refer to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

Referring to FIGS. 1 and 2A, a substrate 100 may be provided thereon with a fin structure FS extending in a second direction D2 (S110). The substrate 100 may be patterned to form trenches 101 defining the fin structure FS. The fin structure FS may protrude from the substrate 100 in a third direction D3 perpendicular to first and second directions D1 and D2 that are perpendicular to each other.

In this exemplary embodiment, the formation of the fin structure FS may include forming a mask pattern 110 on the substrate 100 and anisotropically etching the substrate 100 to form the trenches 101 using the mask pattern 110 as an etch mask. The mask pattern 110 may include a buffer oxide pattern 111 and a hardmask pattern 113 that are sequentially stacked. The formation of the mask pattern 110 may include sequentially stacking a silicon oxide layer and a hardmask layer on the substrate 100, forming on the hardmask layer a photoresist pattern (not shown) defining the fin structure FS, and sequentially anisotropically etching the hardmask layer and the silicon oxide layer until exposing a top surface of the substrate 100 using the photoresist pattern (not shown) as an etch mask. The silicon oxide layer may be formed by performing thermal oxidation on the substrate 100. The hardmask layer may be formed of a material selected from a silicon nitride layer, a silicon oxynitride layer, and a polysilicon layer. The trenches 101 may have a sidewall substantially vertical to the top surface of the substrate 100 in one embodiment or inclined to the top surface of the substrate 100 in another embodiment.

The substrate 100 may include a group III-V semiconductor material. For example, the III-V semiconductor material may include one of indium arsenide (InAs), gallium arsenide (GaAs), aluminum arsenide (AlAs), indium gallium arsenide (InGaAs), indium aluminum arsenide (InAlAs), indium aluminum arsenic antimonide (InAlAsSb), indium phosphide (InP), indium aluminum arsenic phosphide (InAlAsP), indium gallium arsenic phosphide (InGaAsP), gallium arsenic antimonide (GaAsSb), indium aluminum antimonide (InAlSb), indium antimonide (InSb), gallium antimonide (GaSb), aluminum antimonide (AlSb), indium gallium antimonide (InGaSb), aluminum arsenic antimonide (AlAsSb), aluminum arsenide (AlAs), indium gallium phosphide (InGaP), gallium arsenic phosphide (GaAsP), aluminum gallium arsenide (AlGaAs), and any combination thereof.

Referring to FIGS. 1 and 2B, a first preliminary capping layer 120a may be formed on the fin structure FS and the mask pattern 110 (S120). For example, the first preliminary capping layer 120a may cover the top surface of the substrate 100, side walls of the fin structure FS and side walls and top surface of the mask pattern. The first preliminary capping layer 120a may include silicon (Si). The first preliminary capping layer 120a may include one or more of amorphous silicon, polysilicon, and single crystalline silicon. In this exemplary embodiment, after the fin structure FS is formed, a bake process may be performed and then a deposition process may be performed to form the first preliminary capping layer 120a. For example, the bake process may be performed at temperature of less than about 400° C., and the deposition process may be performed at temperature of less than about 350° C. The first preliminary capping layer 120a may be formed to have a thickness of about 2 nm to about 5 nm. As the bake and deposition processes are performed at relatively low temperature, the III-V semiconductor material may be prevented from migration and out-gassing.

Referring to FIGS. 1, 2C, and 2D, device isolation patterns 130 may be formed on the fin structure FS (S130). For example, referring to FIG. 2C, a device isolation layer 130a may be formed on the fin structure FS, and the mask pattern (110 of FIG. 2B) may be removed. The device isolation layer 130a may include oxide. The device isolation layer 130a may be formed to fill the trenches 101 and then planarized until the mask pattern 110 is exposed. In this step, an upper portion of the first preliminary capping layer 120a may be removed. Thereafter, the mask pattern 110 may be removed to form a recess 115. The recess 115 may expose an upper portion of the fin structure FS and a portion of the first preliminary capping layer 120a. For example, in one embodiment, only the sidewalls of the fin structure FS include the first preliminary capping layer 120a and the top most surface of the fin structure FS does not include the first preliminary capping layer 120a

Referring to FIG. 2D, a selective removal may be performed on the portion of the first preliminary capping layer 120a exposed through the recess 115. A partially removed first preliminary capping layer 120a may have a top surface at the same level as a top surface of the fin structure FS. The partial removal of the first preliminary capping layer 120a may include etching the exposed portion of the first preliminary capping layer 120a. Alternatively, the partial removal of the first preliminary capping layer 120a may include oxidizing the exposed portion of the first preliminary capping layer 120a and then etching a produced silicon oxide. The device isolation layer 130a may be recessed on its upper portion to form the device isolation patterns 130 that expose an upper portion of the fin structure FS. The recessing of the upper portion of the device isolation layer 130a may be achieved using, for example, a wet etch process under an etch condition having an etch selectivity to the fin structure FS.

Each of the device isolation patterns 130 may partially expose a sidewall of the fin structure FS. That is, the fin structure FS may have opposite sidewalls that are exposed through the device isolation patterns 130. The fin structure FS may have an upper portion exposed through the device isolation patterns 130 that is defined to refer to an active fin AF, and a lower portion of the active fin AF may be defined to refer to an active pattern AP. Each of the device isolation patterns 130 may have a top surface at a lower level from the substrate 100 than the top surface of the fin structure FS from the substrate 100. The device isolation patterns 130 may extend along the second direction D2 on the substrate 100 and be spaced apart from each other along the first direction D1 across the fin structure FS.

Referring to FIGS. 1 and 2E, the first preliminary capping layer (120b of FIG. 2D) may be partially removed to form a capping layer 120 (S140). The first preliminary capping layer 120b may be removed of its upper portion exposed through the device isolation pattern 130. The capping layer 120 may therefore be present between the substrate 100 and the device isolation patterns 130 and between the fin structure FS and the device isolation patterns 130. The capping layer 120 may have a top surface at substantially same level as a top surface of the device isolation pattern 130. The capping layer 120 may have a top surface at a lower level from the substrate 100 than the top surface of the fin structure FS. The partial removal of the first preliminary capping layer 120b may include etching the exposed portion of the first preliminary capping layer 120b. For example, HF may be used to etch the first preliminary capping layer 120b. In other embodiment, the partial removal of the first preliminary capping layer 120b may include oxidizing the exposed portion of the first preliminary capping layer 120b and then etching a produced silicon oxide.

Referring to FIGS. 1 and 2F, the substrate 100 may be provided thereon with a sacrificial gate structure SGS running across the fin structure FS and the device isolation patterns 130 (S150). The sacrificial gate structure SGS may be defined to include an etch stop pattern 142, a sacrificial gate pattern 144, a gate mask pattern 146, and gate spacers GSP.

For example, the substrate 100 may be provided thereon with an etch stop layer (not shown) and a sacrificial gate layer (not shown) that are sequentially formed to cover the fin structure FS and the device isolation patterns 130. The etch stop layer may include, for example, a silicon oxide layer. The sacrificial gate layer may include a material having an etch selectivity to the etch stop layer. The sacrificial gate layer may include, for example, polysilicon.

The sacrificial gate layer may be patterned to form the sacrificial gate pattern 144. The formation of the sacrificial gate pattern 144 may include forming the gate mask pattern 146 on the sacrificial gate layer and etching the sacrificial gate layer using the gate mask pattern 146 as an etch mask. The gate mask pattern 146 may include, for example, silicon nitride. The etching of the sacrificial gate layer may include performing an etch process having an etch selectivity to the etch stop layer.

After the sacrificial gate pattern 144 is formed, the etch stop layer may be removed from opposite sides of the sacrificial gate pattern 144 such that the etch stop pattern 142 may be formed below the sacrificial gate pattern 144. The etch stop pattern 142 may extend along a bottom surface of the sacrificial gate pattern 144 to cover the top surface and the sidewalls of the fin structure FS and the top surfaces of the device isolation patterns 130.

The gate spacers GSP may be formed on opposite sidewalls of the sacrificial gate pattern 144. The gate spacers GSP may include, for example, silicon nitride. The formation of the gate spacers GSP may include forming a gate spacer layer (not shown) on the substrate 100 on which the sacrificial gate pattern 144 is formed and performing an anisotropic etch process on the gate spacer layer. A portion of the gate mask pattern 146 may be etched during the etch process, and a remaining portion of the gate mask pattern 146 may remain on the sacrificial gate pattern 144 after the etch process.

Referring to FIGS. 1, 2G, and 2H, source/drain regions SD may be formed on opposite sides of the sacrificial gate structure SGS (S160).

Referring to FIG. 2G, a recess may be performed on portions of the active fin AF that are exposed on the opposite sides of the sacrificial gate structure SGS. A dry or wet etch process may be performed to recess or remove the active fin AF. As such, a top surface of the active pattern AP may be exposed on the opposite sides of the sacrificial gate structure SGS.

Referring to FIG. 2H, the source/drain regions SD may be formed on the opposite sides of the sacrificial gate structure SGS. The formation of the source/drain regions SD may include performing a selective epitaxial growth process on the substrate 100. The source/drain regions SD may be an epitaxial pattern grown from the top surface of the active pattern AP serving as a seed. When the semiconductor device (1 of FIG. 2I) is an NMOSFET, the epitaxial pattern may be configured to exert a tensile strain. At the same time or after the epitaxial process, the source/drain regions SD may be doped with impurities. As not shown in figures, the source/drain regions SD may include a plurality of epitaxial patterns.

A lower interlayer dielectric layer 150 may be formed on the substrate 100 on which the source/drain regions SD are formed. The lower interlayer dielectric layer 150 may be formed to cover the source/drain regions SD and the sacrificial gate pattern 144. The lower interlayer dielectric layer 150 may include one or more of a silicon oxide layer, a silicon nitride layer, a silicon oxynitride layer, and a low-k dielectric layer.

Referring to FIGS. 1 and 2I, a gate structure GS may be formed (S170). The gate structure GS may be defined to include a gate dielectric pattern 162, a gate electrode 164, and gate spacers GSP. The gate structure GS may extend in the first direction D1.

The gate mask pattern 146, the sacrificial gate pattern 144, and the etch stop pattern 142 may be removed to form a gap region (not shown) between the gate spacers GSP. During an etch process for removing the gate mask pattern 146, the lower interlayer dielectric layer 150 may also be partially removed. The formation of the gap region may include etching the sacrificial gate pattern 144 by an etch process having an etch selectivity to the gate spacers GSP, the lower interlayer dielectric layer 150, and the etch stop pattern 142. When the gap region is formed, the etch stop pattern 142 may be removed to expose the active fin AP of the fin structure FS.

The gate dielectric pattern 162 and the gate electrode 164 may be formed to fill the gap region. For example, a gate dielectric layer (not shown) may be formed to fill a portion of the gap region on the substrate 100. The gate dielectric layer may be formed to cover the active fin AF of the fin structure FS. The gate dielectric layer may include at least one of high-k dielectric layers. For example, the gate dielectric layer may include one or more of hafnium oxide, hafnium silicate, zirconium oxide, and zirconium silicate, but the present disclosure is not limited to these materials. The gate dielectric layer may be formed by performing atomic layer deposition or chemical vapor deposition. A gate layer (not shown) may be formed on the gate dielectric layer to fill a remaining portion of the gap region. The gate dielectric layer may be formed to have a thickness of about 1 nm to about 2 nm. The gate layer may include one or more of metal nitride (e.g., titanium nitride, tantalum nitride, or tungsten nitride) and metal (e.g., aluminum or tungsten).

A planarization process may be performed on the gate dielectric layer and the gate layer that are sequentially stacked, and thus the gate dielectric pattern 162 and the gate electrode 164 may be formed. The planarization process may expose top surfaces of the lower interlayer dielectric layer 150 and the gate spacers GSP. The gate dielectric pattern 162 may extend along a bottom surface of the gate electrode 164 toward opposite sidewalls of the gate electrode 164 to interpose between the gate electrode 164 and the gate spacers GSP.

According to exemplary embodiments as illustrated in FIGS. 2A-2I, a semiconductor device 1 may include a fin structure FS on a substrate 100; device isolation patterns 130 provided on the substrate 100 and disposed on opposite sides of the fin structure FS; a gate electrode 164 crossing the fin structure FS and the device isolation patterns 130; a gate dielectric pattern 162 between the gate electrode 164 and the fin structure FS and between the gate electrode 164 and the device isolation patterns 130; and a capping layer 120 between the substrate 100 and the devices isolation patterns 130 and between the fin structure FS and the device isolation patterns 130 (e.g., the capping layer 120 may be provided directly between the substrate 100 and the devices isolation patterns 130 and directly between the fin structure FS and the device isolation patterns 130.

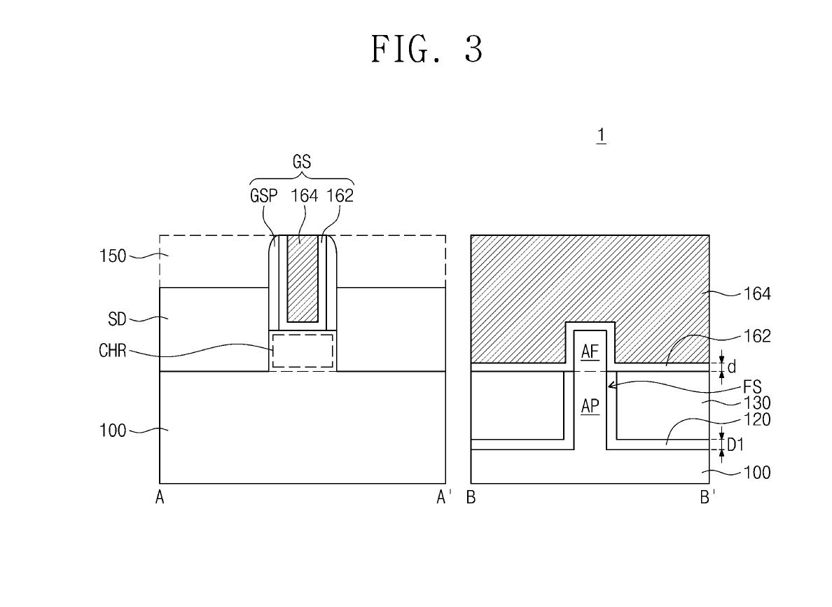

FIG. 3 is a cross-sectional view taken along lines A-A′ and B-B′ of FIG. 2I, illustrating a semiconductor device 1 according to exemplary embodiments of the present disclosure. Referring to FIGS. 2I and 3, a substrate 100 may be provided thereon with a fin structure FS and a gate structure GS running across the fin structure FS. The substrate 100 may include a III-V semiconductor material.

The fin structure FS may have a shape protruding in a direction perpendicular to the substrate 100. The fin structure FS may include an active pattern AP and an active fin AF. The fin structure FS may have an upper portion protruding above device isolation patterns 130 that is defined to refer to the active fin AF, and the active pattern AP may be a lower portion of the active fin AF.

The device isolation patterns 130 may be disposed on opposite sides of the active pattern AP. The device isolation patterns 130 may include oxide, nitride, and/or oxynitride. The device isolation patterns 130 may have a shape extending along a second direction D2. The device isolation patterns 130 may be spaced apart from each other along a first direction D1 across the active pattern AP. The device isolation patterns 130 may cover opposite sidewalls of the active pattern AP.

A capping layer 120 may be disposed between the active patterns AP and the device isolation patterns 130 and between the substrate 100 and the device isolation patterns 130. For example, the capping layer 120 may be disposed on the opposite sidewalls of the active pattern AP. The capping layer 120 may include silicon, which may be but not limited to amorphous, polycrystalline, or single crystalline.

The gate structure GS may extend in the first direction D1. The gate structure GS may run across (e.g., crossing) the active fin AF. The gate structure GS may cover a top surface and opposite sidewalls of the active fin AF. The active fin AF may be locally disposed below the gate structure GS. The active fin AF may include a channel region CHR.

The gate structure GS may include a gate electrode 164 running across the active fin AF, gate spacers GSP on opposite sidewalls of the gate electrode 164, and a gate dielectric pattern 162 between the gate electrode 164 and the gate spacers GSP. The gate dielectric pattern 162 may be disposed between that gate electrode 164 and the active fin AF, and horizontally extend from the active fin AF to partially cover a top surface of each of the device isolation patterns 130. For example, the gate dielectric pattern 162 may be disposed on the opposite sidewalls of the active fin AF. The gate dielectric pattern 162 may extend along a bottom surface of the gate electrode 164.

The capping layer 120 may have a first thickness D1. For example, the first thickness D1 may be in the range from about 2 nm to about 5 nm. In contrast, when a thin capping layer is provided, an upper portion of the capping layer is oxidized during the formation of the device isolation patterns 130. According to the present disclosure, the capping layer 120 may have such a sufficient thickness that excellent adhesion may be obtained between the substrate 100 and the device isolation patterns 130. The gate dielectric pattern 162 may have a thickness d equal to or smaller than the first thickness D1. In some embodiments, the thickness d of the gate dielectric pattern 162 may be smaller than the first thickness D1. For example, the thickness d may be in the range from about 1 nm to about 2 nm.

In some embodiments, adhesion may be improved between the substrate 100 including group III-V semiconductor and the device isolation patterns 130 including silicon oxide. In contrast, in a conventional semiconductor device, as adhesion is weak at an interface between group III-V semiconductor and silicon oxide, when a device isolation layer is recessed after a fin structure is formed, a ditch phenomenon may occur to excavate between the fin structure and device isolation patterns.

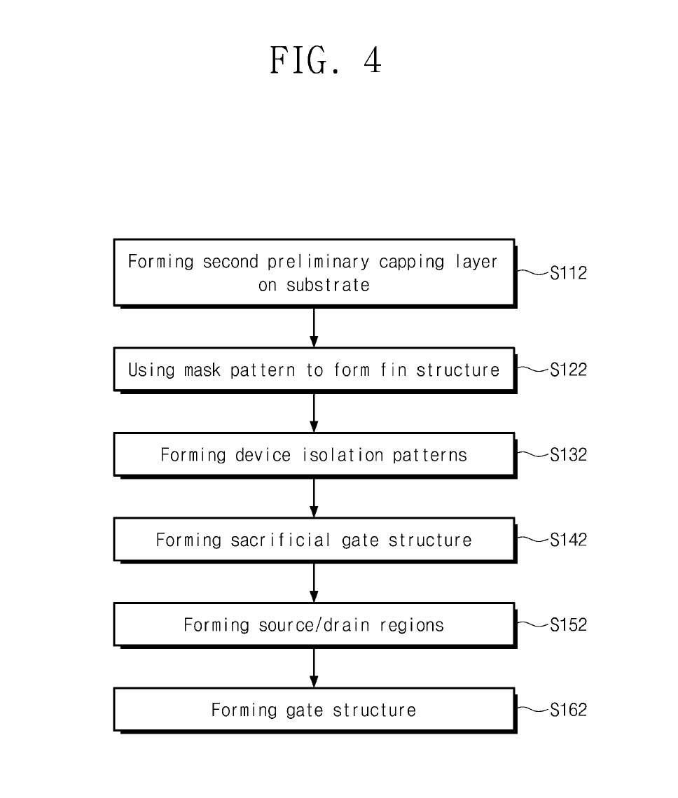

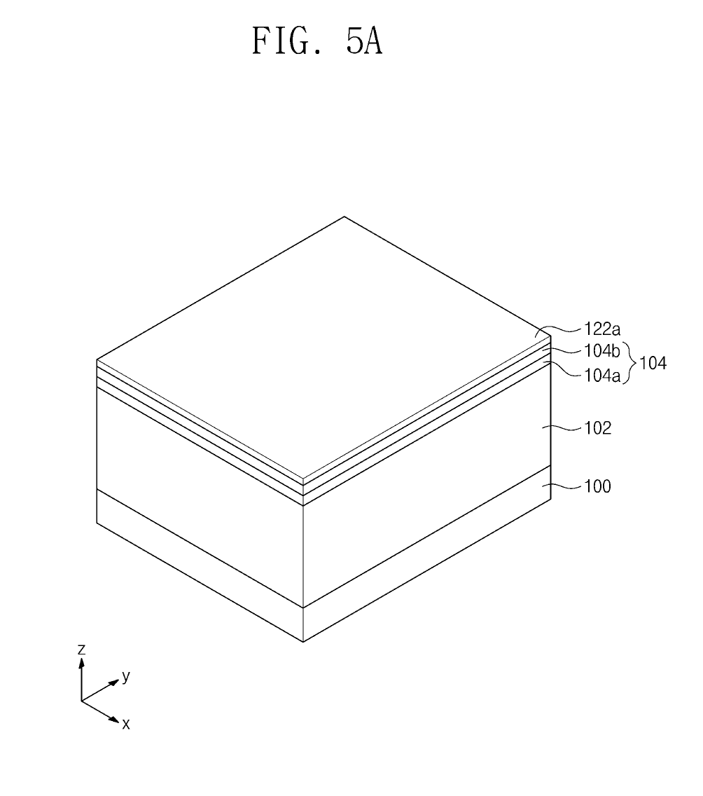

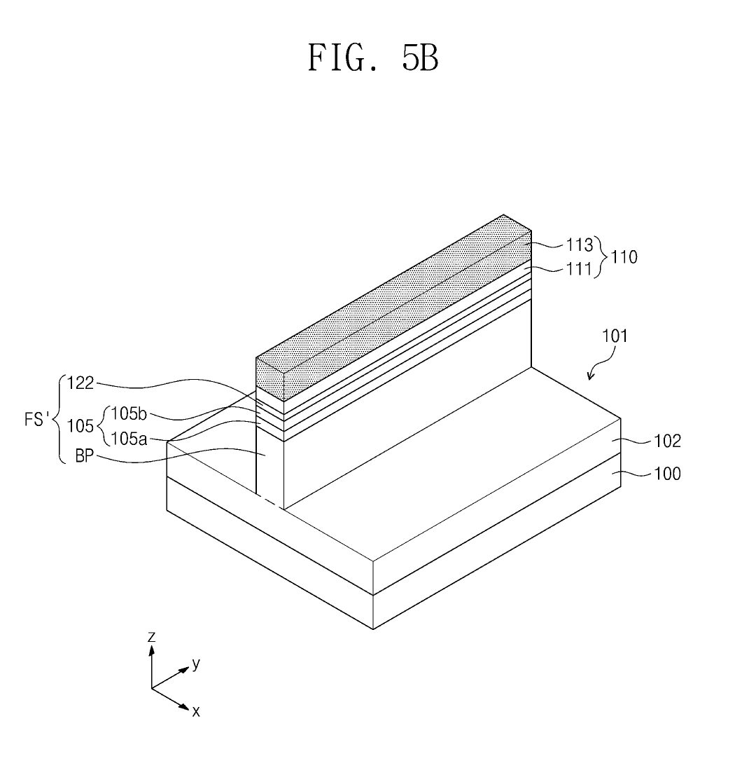

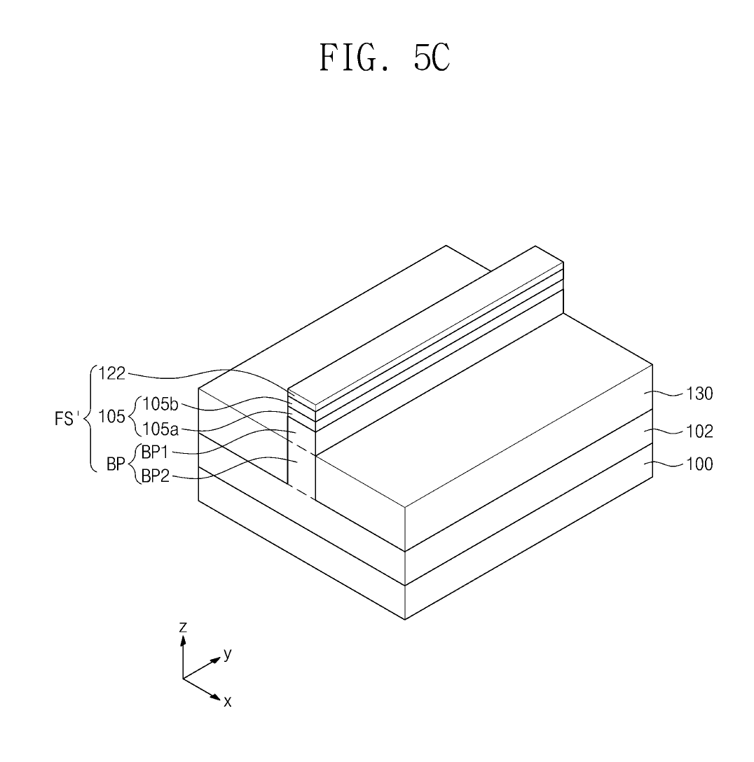

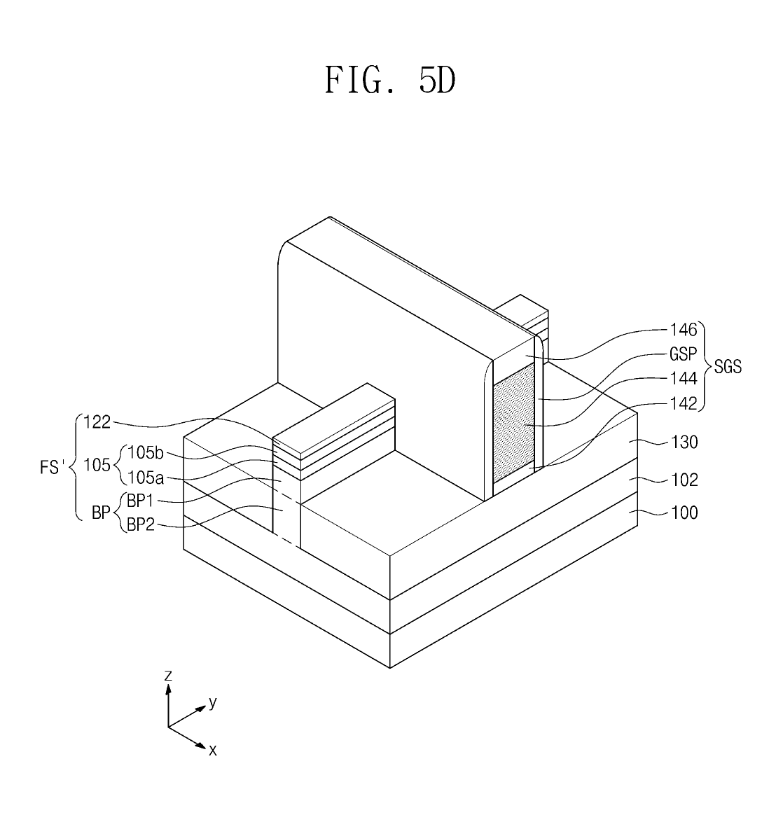

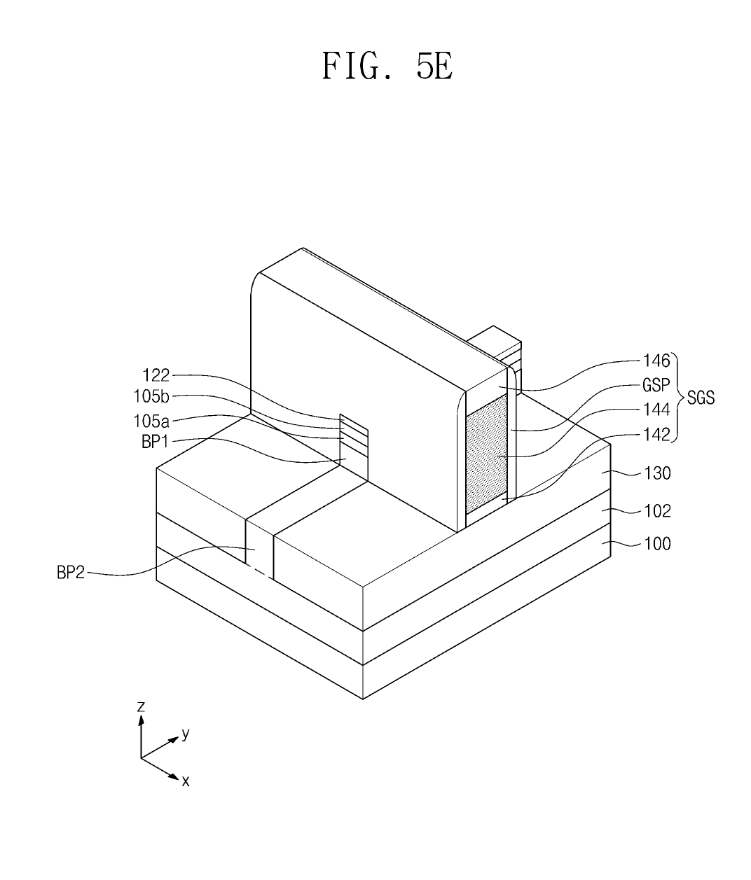

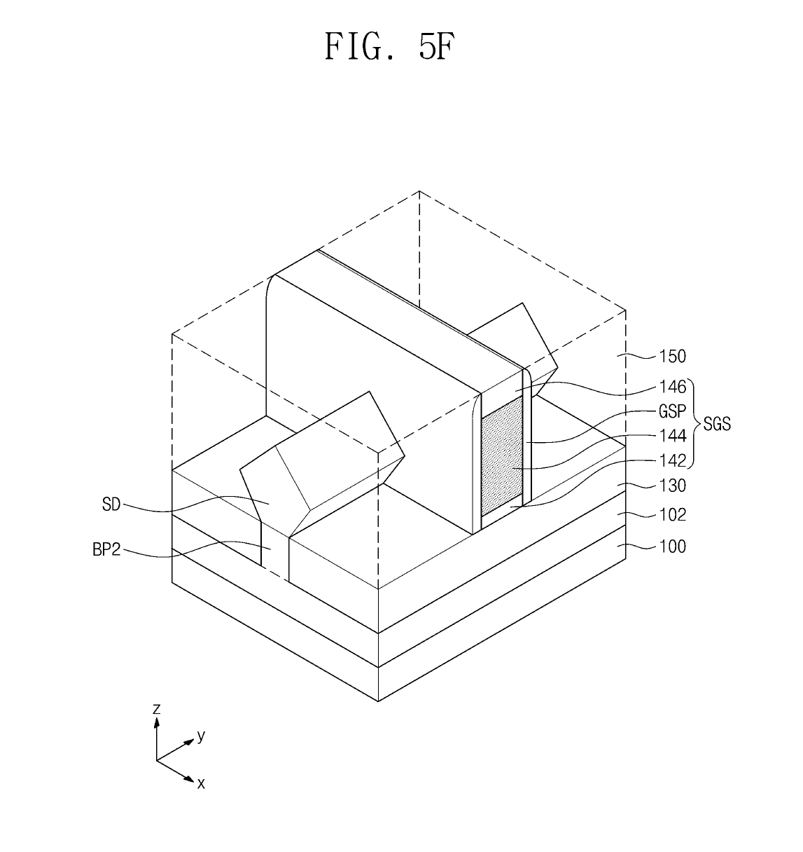

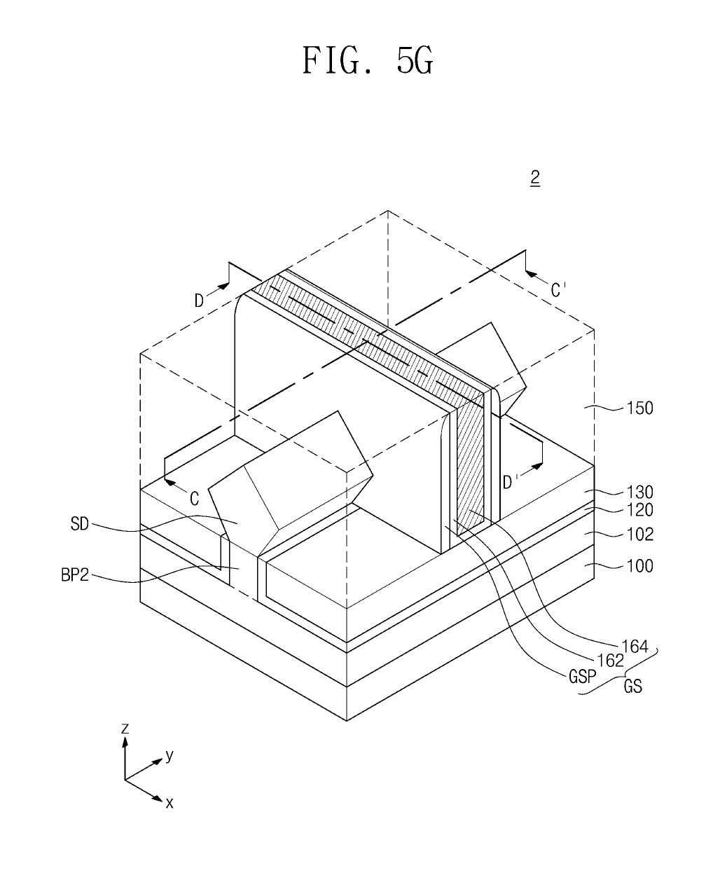

FIG. 4 is a flow chart illustrating a method of fabricating a semiconductor device according to exemplary embodiments of the present disclosure. FIGS. 5A to 5H are perspective views illustrating a method of fabricating a semiconductor device 2 in accordance with FIG. 4. It will be described a method of fabricating the semiconductor device 2 according to exemplary embodiments of the present disclosure with reference to FIGS. 4 to 5H.

Referring to FIGS. 4 and 5A, a second preliminary capping layer 122a may be formed on a substrate 100 (S112). A buffer layer 102 and an active layer 104 may be sequentially stacked on the substrate 100. For example, the buffer layer 102 may be formed on the upper surface of the substrate 100, the active layer 104 may be formed on the upper surface of the buffer layer 102 and the second preliminary capping layer 122a may be formed on the upper surface of active layer 104 such that the buffer layer 102 is provided between the substrate 100 and the active layer 104 and the active layer 104 is provided between the buffer layer 102 and the second preliminary capping layer 122a. The substrate 100 may be a semiconductor substrate. For example, the substrate 100 may be a silicon substrate or an SOI (Silicon-On-Insulator) substrate. The buffer layer 102 may alleviate difference in lattice constant between the substrate 100 and the active layer 104. The buffer layer 102 may include a semiconductor material whose lattice constant is different from that of the substrate 100. The lattice constant of the buffer layer 102 may be greater than that of the substrate 100 and smaller than that of the active layer 104. For example, the buffer layer 102 may include Si, Ge, SiGe, or III-V group compound. For example, the III-V group compound may be one or more of aluminum phosphide (AlP), gallium phosphide (GaP), indium phosphide (InP), aluminum arsenide (AlAs), gallium arsenide (GaAs), indium arsenide (InAs), aluminum antimonide (AlSb), gallium antimonide (GaSb), and indium antimonide (InSb).

In some embodiments, the buffer layer 102 may be formed by a selective epitaxial growth (SEG) process using the substrate 100 as a seed. For example, solid phase epitaxy (SPE), vapor phase epitaxy (VPE), or liquid phase epitaxy (LPE) may be adopted as the selective epitaxial growth process. In some embodiments, the buffer layer 102 may be formed by vapor phase epitaxy (VPE), chemical vapor deposition (CVD), reduced pressure chemical vapor deposition (RPCVD), ultra high vacuum chemical vapor deposition (UHCVD), or molecular beam epitaxy (MBE).

The active layer 104 may include a plurality of active layers. For example, the active layer 104 may include but not limited to first and second sub-active layers 104a and 104b that are sequentially stacked. The active layer 104 may include a group III-V semiconductor material. The group III-V semiconductor material may include one of indium arsenide (InAs), gallium arsenide (GaAs), aluminum arsenide (AlAs), indium gallium arsenide (InGaAs), indium aluminum arsenide (InAlAs), indium aluminum arsenic antimonide (InAlAsSb), indium phosphide (InP), indium aluminum arsenic phosphide (InAlAsP), indium gallium arsenic phosphide (InGaAsP), gallium arsenic antimonide (GaAsSb), indium aluminum antimonide (InAlSb), indium antimonide (InSb), gallium antimonide (GaSb), aluminum antimonide (AlSb), indium gallium antimonide (InGaSb), aluminum arsenic antimonide (AlAsSb), aluminum arsenide (AlAs), indium gallium phosphide (InGaP), gallium arsenic phosphide (GaAsP), aluminum gallium arsenide (AlGaAs), and any combination thereof. For example, each of the first and second sub-active layers 104a and 104b may include indium gallium arsenide (InGaAs) and/or indium phosphide (InP).

The second preliminary capping layer 122a may be formed on the active layer 104. The second preliminary capping layer 122a may include silicon (Si). The second preliminary capping layer 122a may include one or more of amorphous silicon, polysilicon, and single crystalline silicon. A deposition process for forming the second preliminary capping layer 122a may be performed at temperature of less than about 350° C. The second preliminary capping layer 122a may be formed to have a thickness of about 1 nm to about 5 nm. As the deposition process is performed at relatively low temperature, the III-V semiconductor material may be prevented from migration and out-gassing.

Referring to FIGS. 4 and 5B, the substrate 100 may be provided thereon with a fin structure FS′ extending in a second direction D2 (S122). The substrate 100, the buffer layer 102, and the active layer 104 may be patterned to form trenches 101 defining the fin structure FS′. The fin structure FS′ may protrude from the substrate 100 in a third direction D3 perpendicular to first and second directions D1 and D2 that are perpendicular to each other.

The fin structure FS′ may be defined to include a buffer pattern BP, a channel pattern 105, and a capping pattern 122. The buffer pattern BP may be a portion of the buffer layer 102 and may protrude in the third direction D3 from the buffer layer 102. The channel pattern 105 may be disposed on the buffer pattern BP. The channel pattern 105 may include first and second patterns 105a and 105b that are sequentially stacked such that the first pattern 105a is provided between the buffer pattern BP and second pattern 105b and the capping pattern 122 is formed on an upper surface of the second pattern 105b. The channel pattern 105 may be provided as a plurality of layers such that quantum well effect may increase and leakage current may decrease, but the present disclosure is not limited thereto; for example, the channel pattern 105 may be provided as a single layer. The capping pattern 122 may be disposed on the channel pattern 105. The capping pattern 122 may occupy an uppermost portion of the fin structure FS′.

For example, the formation of the fin structure FS′ may include forming a mask pattern 110 on the active layer 104 and anisotropically etching the second preliminary capping layer 122a, the active layer 104, and the buffer layer 102 to form the trenches 101 using the mask pattern 110 as an etch mask. The mask pattern 110 may include a buffer oxide pattern 111 and a hardmask pattern 113 that are sequentially stacked.

For example, the formation of the mask pattern 110 may include sequentially stacking a silicon oxide layer and a hardmask layer on the substrate 100, forming on the hardmask layer a photoresist pattern (not shown) defining the fin structure FS′, and sequentially anisotropically etching the hardmask layer and the silicon oxide layer using the photoresist pattern (not shown) as an etch mask. The hardmask layer may be formed of a material selected from a silicon nitride layer, a silicon oxynitride layer, and a polysilicon layer. The trenches 101 may have a sidewall substantially vertical or inclined to a top surface of the substrate 100.

Referring to FIGS. 4 and 5C, device isolation patterns 130 may be formed on the fin structure FS′ (S132). For example, a device isolation layer (not shown) may be formed on the fin structure FS′, and the mask pattern (110 of FIG. 5B) may be removed. The device isolation layer may include oxide. The device isolation layer may be formed to fill the trenches 101 and then planarized until the mask pattern 110 is exposed, and the mask pattern 110 may be removed. The device isolation layer may be recessed on its upper portion to form the device isolation patterns 130 that expose an upper portion of the fin structure FS′. The recessing of the upper portion of the device isolation layer may be achieved using, for example, a wet etch process under an etch condition having an etch selectivity to the fin structure FS′.

Each of the device isolation patterns 130 may partially expose a sidewall of the fin structure FS′. That is, the fin structure FS′ may have opposite sidewalls exposed through the device isolation patterns 130. The upper portion of the fin structure FS′ exposed through the device isolation patterns 130 may include the capping pattern 122, the channel pattern 105, and a portion of the buffer pattern BP. In this description, a first buffer pattern BP1 may be defined to indicate the portion of the buffer pattern BP exposed through the devices isolation patterns 130, and a second buffer pattern BP2 may be defined to indicate a lower portion of the first buffer pattern BP1. The present disclosure, however, is not limited thereto. Alternatively, the upper portion of the fin structure FS′ exposed through the device isolation patterns 130 may include the capping pattern 122 and the channel pattern 105. Each of the device isolation patterns 130 may have a top surface at a lower level from the substrate 100 than a top surface of the fin structure FS′. The device isolation patterns 130 may extend along the second direction D2 on the substrate 100 and be spaced apart from each other along the first direction D1 across the fin structure FS′.

As not shown in figures, a process may be selectively performed to thin the capping pattern 122. For example, a portion of the capping pattern 122 may be oxidized to produce silicon oxide at an upper portion of the capping pattern 122. A remaining capping pattern 122 may have a thickness in the range, for example, from about 0.5 nm to about 1 nm.

Referring to FIGS. 4 and 5D, the substrate 100 may be provided thereon with a sacrificial gate structure SGS running across the fin structure FS′ and the device isolation patterns 130 (S142). In this description, the sacrificial gate structure SGS may be defined to include an etch stop pattern 142, a sacrificial gate pattern 144, a gate mask pattern 146, and gate spacers GSP. The formation process and structural configuration of the sacrificial gate structure SGS may be identical or similar to those described with reference to FIG. 2F, and thus a repetitive explanation thereof will be omitted.

Referring to FIGS. 4, 5E, and 5F, source/drain regions SD may be formed on opposite sides of the sacrificial gate structure SGS (S152). The formation process and structural configuration of the source/drain regions SD may be identical or similar to those described with reference to FIGS. 2G and 2H, and thus a repetitive explanation thereof will be omitted.

Referring to FIG. 5E, a recessing may be performed on the first buffer pattern BP1, the channel pattern 105, and the capping pattern 122 that are exposed on the opposite sides of the sacrificial gate structure SGS. A dry or wet etch process may be carried out to recess or remove the first buffer pattern BP1, the channel pattern 105, and the capping pattern 122. As such, a top surface of the second buffer pattern BP2 may be exposed on the opposite sides of the sacrificial gate structure SGS. Referring to FIG. 5F, the source/drain regions SD may be formed on the opposite sides of the sacrificial gate structure SGS. The source/drain regions SD may be an epitaxial pattern grown from the top surface of the second buffer pattern BP2 serving as a seed.

A lower interlayer dielectric layer 150 may be formed on the substrate 100 on which the source/drain regions SD are formed. The lower interlayer dielectric layer 150 may be formed to cover the source/drain regions SD and the sacrificial gate pattern 144. The lower interlayer dielectric layer 150 may include one or more of a silicon oxide layer, a silicon nitride layer, a silicon oxynitride layer, and a low-k dielectric layer.

Referring to FIGS. 4 and 5G, a gate structure GS may be formed (S162). The gate structure GS may be defined to include a gate dielectric pattern 162, a gate electrode 164, and gate spacers GSP. The gate structure GS may extend in the first direction D1. The formation process and structural configuration of the gate structure GS may be identical or similar to those described with reference to FIG. 2I, and thus a repetitive explanation thereof will be omitted.

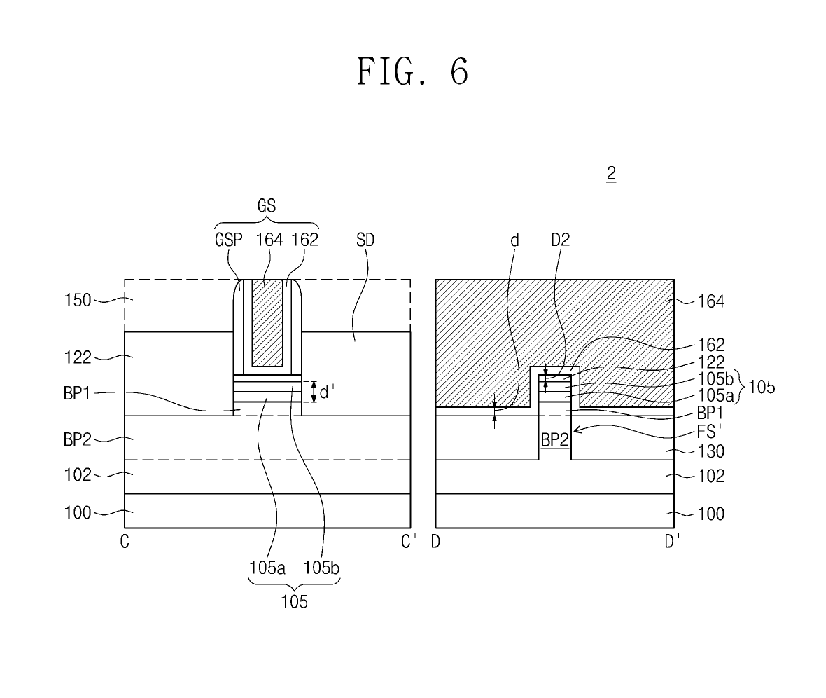

FIG. 6 is a cross-sectional view taken along lines C-C′ and D-D′ of FIG. 5G, illustrating a semiconductor device 2 according to exemplary embodiments of the present disclosure. In the embodiment that follows, component substantially the same as those of the semiconductor device 1 discussed with reference to FIGS. 2I and 3 are allocated the same reference numerals thereto, and a repetitive description thereof may be omitted in the interest of brevity of the description. Referring to FIGS. 5G and 6, a substrate 100 may be provided thereon with a fin structure FS′ and a gate structure GS running across the fin structure FS′.

For example, the substrate 100 may be a silicon substrate or an SOI (Silicon-On-Insulator) substrate. A buffer layer 102 may be provided on the substrate 100. The fin structure FS′ may have a shape protruding in a direction perpendicular to the substrate 100. The fin structure FS′ may include buffer patterns BP1 and BP2, a channel pattern 105, and a capping pattern 122 that are sequentially stacked. The buffer patterns BP1 and BP2 may include a first buffer pattern BP1 protruding above device isolation patterns 130 and a second buffer pattern BP2 below the first buffer pattern BP1. The channel pattern 105 may include first and second sub-channel patterns 105a and 105b that are sequentially stacked on the buffer patterns BP1 and BP2. For example, the first sub-channel pattern 105a is provided between the second sub-channel pattern 105b and the first buffer pattern BP1. The capping pattern 122 may include one or more of amorphous silicon, polysilicon, and single crystalline silicon. The capping pattern 122 may have a second thickness D2 (e.g., a second thickness D2 in an upward direction (e.g., direction D3) perpendicular to the substrate 100). For example, the second thickness D2 may be in the range from about 0.5 nm to about 1 nm. A gate dielectric pattern 162 may have a thickness d (e.g., a thickness d in an upward direction (e.g., direction D3) perpendicular to the substrate 100) greater than the second thickness D2. For example, the thickness d of the gate dielectric pattern 162 may be in the range from about 1 nm to about 2 nm. The channel pattern 105 may have a thickness d′ (e.g., a thickness d′ in an upward direction (e.g., direction D3) perpendicular to the substrate 100) greater than the second thickness D2. For example, the thickness d′ of the channel pattern 105 may be in the range from about 2 nm to about 5 nm. In some embodiments, the thickness d′ of the channel pattern 105 may be greater than the thickness d of the gate dielectric pattern 162. As the capping pattern 122 is provided as a thin-layer, the channel pattern 105 may have no effect on its function as a channel.

In some embodiments, excellent adhesion may be obtained between the substrate 100 including III-V semiconductor and the mask pattern 110 including silicon oxide by, for example, the above described process. In contrast, in a general semiconductor device, as adhesion is weak at an interface between III-V semiconductor and silicon oxide, when a cleaning process is performed after a fin structure is formed, a lift-off phenomenon may occur to collapse the mask pattern.

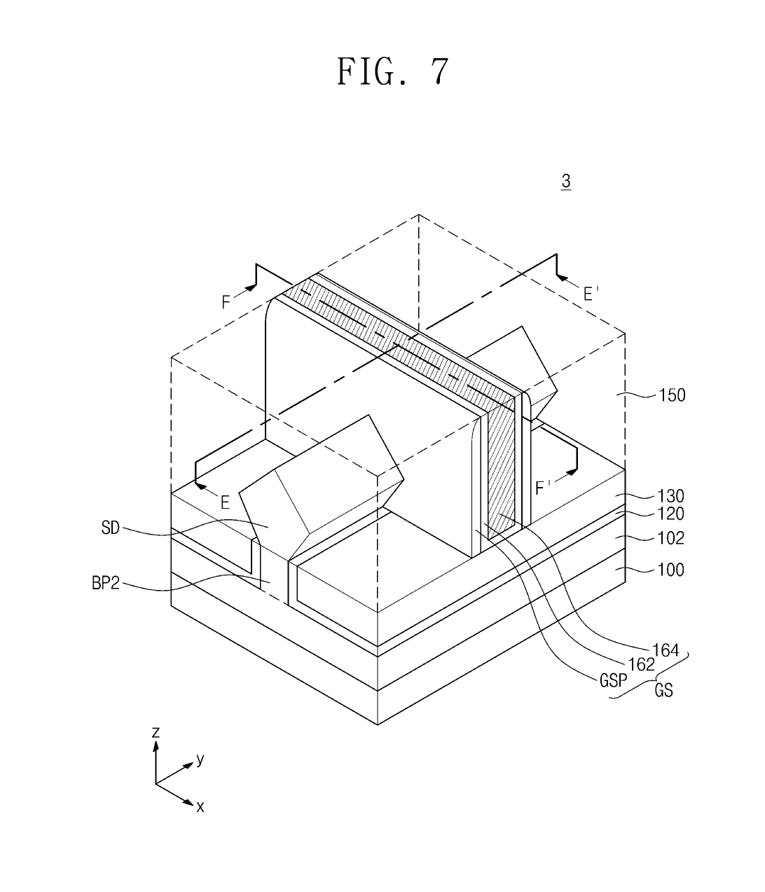

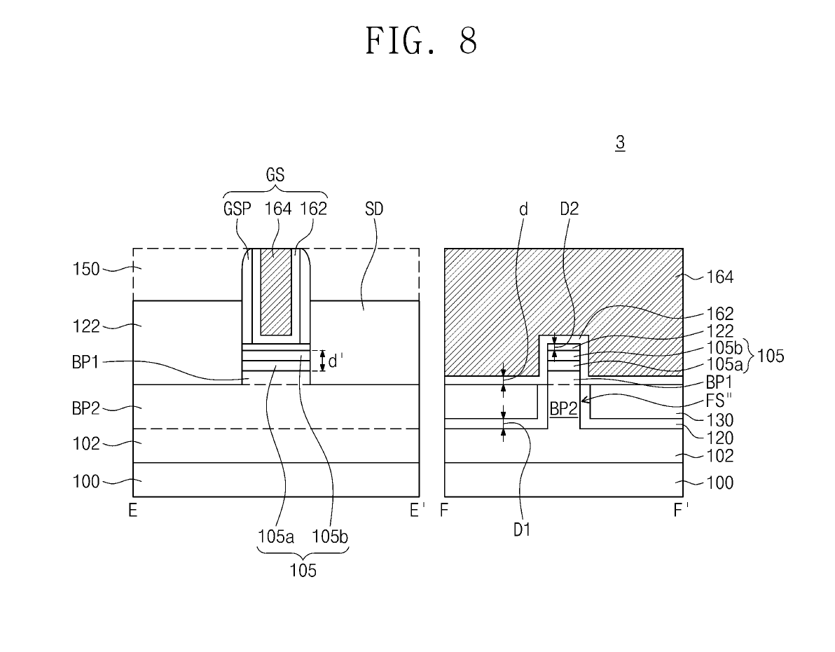

FIG. 7 is a perspective view illustrating a semiconductor device 3 according to exemplary embodiments of the present disclosure. FIG. 8 is a cross-sectional view taken along lines E-E′ and F-F′ of FIG. 7. In the embodiment that follows, component substantially the same as those of the semiconductor devices 1 and 2 discussed with reference to FIGS. 2I, 3, 5G, and 6 are allocated the same reference numerals thereto, and a repetitive description thereof may be omitted in the interest of brevity of the description.

Referring to FIGS. 7 and 8, a substrate 100 may be provided thereon with a fin structure FS″ and a gate structure GS running across the fin structure FS″.

The fin structure FS″ may include first and second buffer patterns BP1 and BP2, a channel pattern 105, and a capping pattern 122 that are sequentially stacked. For example, the channel pattern 105 is provided or formed between the first buffer pattern BP1 and the capping pattern 122 and the first buffer pattern BP1 is provided or formed between the second buffer pattern BP2 and the channel pattern 105. For example, the channel pattern 105 may be provided or formed directly between the first buffer pattern BP1 and the capping pattern 122 and the first buffer pattern BP1 may be provided or formed directly between the second buffer pattern BP2 and the channel pattern 105. A capping layer 120 may be disposed on opposite sidewalls of the second buffer pattern BP2. The capping layer 120 may have a first thickness D1 (e.g., a first thickness D1 in an upward direction (e.g., direction D3) perpendicular to the substrate 100), and the capping pattern 122 may have a second thickness D2 less than the first thickness D1. For example, the first thickness D1 may be in the range from about 2 nm to about 5 nm, and the second thickness D2 may be in the range from about 0.5 nm to about 1 nm. A gate dielectric pattern 162 may have a thickness d equal to or smaller than the first thickness D1 and equal to or greater than the second thickness D2. For example, the thickness d of the gate dielectric pattern 162 may be in the range from about 1 nm to about 2 nm. The channel pattern 105 may have a thickness d′ greater than the second thickness D2. For example, the thickness d′ of the channel pattern 105 may be in the range from about 2 nm to about 5 nm. As the capping pattern 122 is provided as a thin-layer, the channel pattern 105 may have no effect on its function as a channel.

The semiconductor device 3 may be fabricated by performing the following steps: forming a second preliminary capping layer on the substrate 100 (S112 of FIG. 4); forming a fin structure (S122 of FIG. 4) (in some embodiments, a mask pattern may be used to form the fin structure); forming a first preliminary capping layer (S120 of FIG. 1); forming device isolation patterns (S130 of FIG. 1); forming a capping layer (S140 of FIG. 1) (in some embodiments, a portion of the first preliminary capping layer may be removed to form the capping layer); forming a sacrificial gate structure (S150 of FIG. 1); forming source/drain regions (S160 of FIG. 1); and forming a gate structure (S170 of FIG. 1). The steps S112 and S122 are described above with reference to FIGS. 4 to 5B, and the remaining steps S120 to S170 are already described with reference to FIGS. 1 to 2I. In the current embodiment, the formation steps are performed differently from the described order, and a repetitive explanation thereof will be omitted.

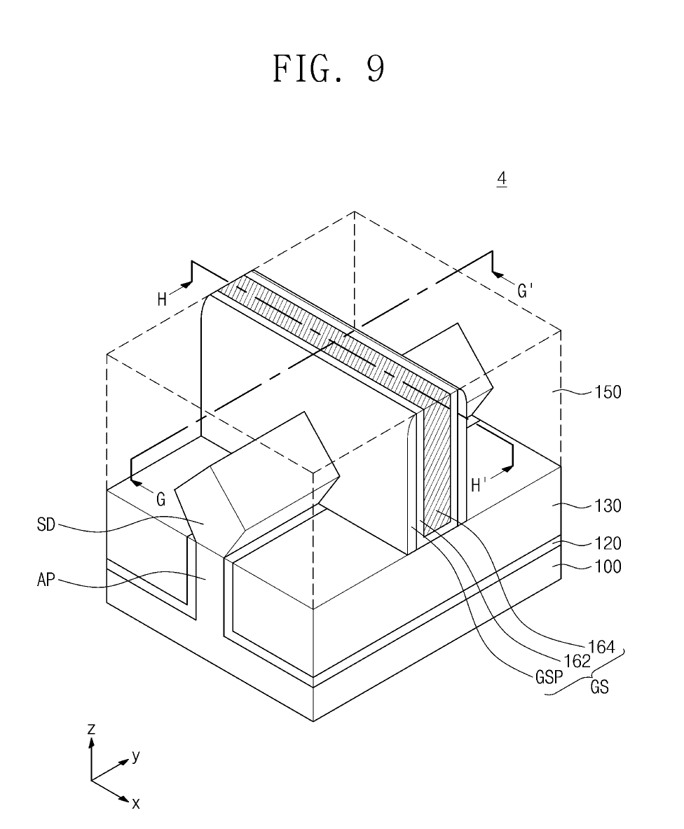

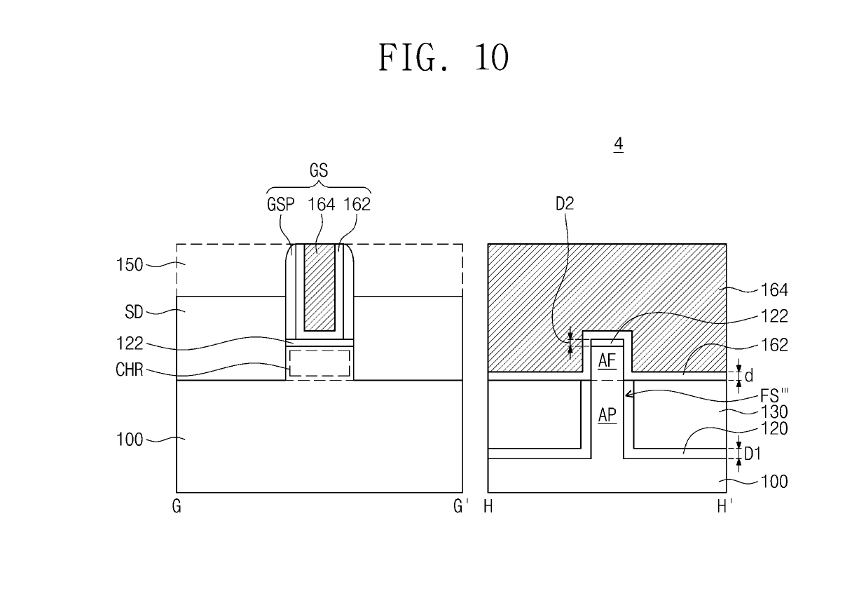

FIG. 9 is a perspective view illustrating a semiconductor device 4 according to exemplary embodiments of the present disclosure. FIG. 10 is a cross-sectional view taken along lines G-G′ and H-H′ of FIG. 9. In the embodiment that follows, component substantially the same as those of the semiconductor devices 1 and 2 discussed with reference to FIGS. 2I, 3, 5G, and 6 are allocated the same reference numerals thereto, and a repetitive description thereof may be omitted in the interest of brevity of the description.

Referring to FIGS. 9 and 10, a substrate 100 may be provided thereon with a fin structure FS″′ and a gate structure GS running across the fin structure FS″′.

The fin structure FS″′ may include an active pattern AP, an active fin AF, and a capping pattern 122. A capping layer 120 may have a first thickness D1, and the capping pattern 122 may have a second thickness D2 less than the first thickness D1. For example, the first thickness D1 may be in the range from about 2 nm to about 5 nm, and the second thickness D2 may be in the range from about 0.5 nm to about 1 nm. A gate dielectric pattern 162 may have a thickness d equal to or smaller than the first thickness D1 and equal to or greater than the second thickness D2. For example, the thickness d of the gate dielectric pattern 162 may be in the range from about 1 nm to about 2 nm.

The semiconductor device 4 may be fabricated by performing the following steps: forming a second preliminary capping layer on the substrate 100 (S112 of FIG. 4); forming a fin structure on the substrate 100 (S110 of FIG. 1); forming a first preliminary capping layer (S120 of FIG. 1) (in some embodiments, the first preliminary capping layer may be formed on the fin structure); forming device isolation patterns (S130 of FIG. 1); forming a capping layer (in some embodiments, the capping layer may be formed by removing a portion of the first preliminary capping layer) (S140 of FIG. 1); forming a sacrificial gate structure (S150 of FIG. 1); forming source/drain regions (S160 of FIG. 1); and forming a gate structure (S170 of FIG. 1). The step S112 is described above with reference to FIGS. 4 to 5A, and the remaining steps S110 to S170 are already described with reference to FIGS. 1 to 2I. In the current embodiment, the formation steps are performed differently from the described order, and a repetitive explanation thereof will be omitted.

Although the present disclosure exemplarily illustrates the semiconductor devices having a single fin structure, each of the semiconductor devices may alternatively have a plurality of fin structures. A MOSFET is exemplarily explained as the semiconductor device in which a capping layer and/or capping pattern is used to obtain strong adhesion at an interface between III-V semiconductor and silicon oxide, but the kind of semiconductor device is not limited thereto. The present disclosure may be applicable to various kinds of patterning method including an interface between III-V semiconductor and silicon oxide.

According to exemplary embodiments of the present disclosure, enhanced adhesion may be obtained between a substrate including a III-V semiconductor material and patterns (e.g., device isolation patterns and/or a mask pattern) including silicon oxide.

The effects of the present disclosure are not limited to the aforementioned effects. Other effects, which are not mentioned above, will be apparently understood by one skilled in the art from the foregoing description and accompanying drawings.

These embodiments herein are presented to facilitate understanding of the present disclosure and should not limit the scope of the present disclosure, and it is intended that the present disclosure covers the various combinations, the modifications, and variations. The technical protection scope of the present disclosure will be defined by the technical spirit of the appended claims, and is intended to include all modifications and equivalent substantially falling within the spirit and scope of the invention while not being limited by literary descriptions in the appended claims.

What is claimed is:

1. A semiconductor device, comprising:
a fin structure on a substrate;
device isolation patterns provided on the substrate and disposed on opposite sides of the fin structure;
a gate electrode running across the fin structure and the device isolation patterns;
a gate dielectric pattern between the gate electrode and the fin structure and between the gate electrode and the device isolation patterns; and
a capping layer between the substrate and the device isolation patterns and between the fin structure and the device isolation patterns,
wherein the capping layer has a thickness greater than a thickness of the gate dielectric pattern.

2. The semiconductor device of claim 1, wherein the fin structure comprises:
an active pattern;
an active fin that occupies an upper portion of the active pattern and protrudes from the device isolation patterns; and
a capping pattern on the active fin.

3. The semiconductor device of claim 2, wherein the thickness of the capping layer is greater than a thickness of the capping pattern.

4. The semiconductor device of claim 2, wherein the capping pattern has a thickness less than the thickness of the gate dielectric pattern.

5. The semiconductor device of claim 2, wherein the capping pattern comprises silicon.

6. The semiconductor device of claim 1, further comprising a buffer layer between the substrate and the fin structure, wherein the fin structure protrudes from the buffer layer, and
wherein the fin structure comprises:
a buffer pattern on the buffer layer;
a channel pattern on the buffer pattern; and
a capping pattern on the channel pattern.

7. The semiconductor device of claim 6, wherein the channel pattern comprises a III-V group compound.

8. The semiconductor device of claim 6, wherein the capping pattern comprises silicon.

9. The semiconductor device of claim 6, wherein the capping pattern has a thickness less than a thickness of the channel pattern.

10. The semiconductor device of claim 6, wherein the buffer pattern comprises:
a first buffer pattern protruding from the device isolation patterns; and
a second buffer pattern below the first buffer pattern.

11. The semiconductor device of claim 1, wherein the capping layer comprises silicon.

12. The semiconductor device of claim 1, wherein the substrate comprises a III-V group compound.

13. A semiconductor device, comprising:
a buffer layer on a substrate;
a fin structure protruding from the buffer layer; and
a gate electrode running across the fin structure,
wherein the fin structure comprises:
a buffer pattern on the buffer layer;
a channel pattern on the buffer pattern; and
a capping pattern on the channel pattern,
wherein the capping pattern has a thickness less than a thickness of the channel pattern.

14. The semiconductor device of claim 13, further comprising a gate dielectric pattern between the gate electrode and the fin structure,
wherein the thickness of the capping pattern is less than a thickness of the gate dielectric pattern.

15. The semiconductor device of claim 13, wherein the channel pattern comprises a group compound, and the capping pattern comprises silicon.

16. A semiconductor device, comprising:
a fin structure on a substrate;
a buffer layer between the substrate and the fin structure;
device isolation patterns provided on the substrate and disposed on opposite sides of the fin structure, the device isolation patterns being spaced apart from each other along the first direction across the fin structure and extending along a second direction on the substrate;
a gate structure crossing the fin structure and the device isolation patterns in the first direction; and
a capping layer between the substrate and the devices isolation patterns and between the fin structure and the device isolation patterns, the capping layer having a top surface at a same level as a top surface of the device isolation patterns and at a lower level from the substrate than a top surface of the fin structure.

17. The semiconductor device of claim 16, wherein the gate structure comprises:
a gate electrode crossing the fin structure and the device isolation patterns; and
a gate dielectric pattern between the gate electrode and the fin structure and between the gate electrode and the device isolation patterns,
wherein the capping layer has a thickness greater than a thickness of the gate dielectric pattern.

18. The semiconductor device of claim 16, wherein the fin structure comprises:
a first buffer pattern and a second buffer pattern;
a channel pattern; and
a capping pattern,
wherein the channel pattern is formed between the first buffer pattern and the capping pattern and the first buffer pattern is formed between the second buffer pattern and the channel pattern.

19. The semiconductor device of claim 18, wherein the channel pattern comprises a III-V group compound.

20. The semiconductor device of claim 18, wherein the capping pattern has a thickness less than a thickness of the channel pattern.
